(19) United States
(12) Patent Application Publication
(10) Pub. No.: US 2026/0369965 A1
(43) Pub. Date: Nov. 19, 2026

(54) SEMICONDUCTOR STRUCTURE FOR FORMING VERTICAL-CAVITY LASER DIODES

(71) Applicant: Soitec, BERNIN (FR)

(72) Inventor: Christophe Figuet, BERNIN (FR)

(21) Appl. No.: 19/158,751

(22) PCT Filed: Jan. 17, 2024
(86) PCT No.: PCT/EP2024/050979

§ 371 Date: Aug. 21, 2025

(30) Foreign Application Priority Data
Feb. 27, 2023 (FR) FR2301768

(51) Int. Cl. H01S 5/183; H01S 5/02

(52) U.S. Cl. CPC H01S 5/18377; H01S 5/0208; H01S 5/0216; H01S 5/0217; H01S 5/18305

(57) ABSTRACT

A semiconductor structure for forming one or more vertical-cavity laser gdiodes includes:
a stack of semiconductor layers based on III-V elements defining an upper Bragg mirror, positioned on an active layer constituted by at least one quantum well permitting laser emission at a defined wavelength, the active layer being positioned on a lower Bragg mirror, the laser emission being intended to exit from the stack via the lower Bragg mirror;
a semiconductor contact film, positioned directly below the lower Bragg mirror, the contact film having a first thickness and a first complex refraction index n₁′=n₁+i.k₁, where n₁ is the first refraction index and k₁ is the first extinction coefficient for the defined wavelength;
a semi-insulating gallium arsenide, support substrate;
an oxide layer in contact with a front face of the support substrate, and positioned between the front face and the contact film, the oxide layer having a second thickness and a second complex refraction index n₂′=n₂+i.k₂, where n₂ is the second refraction index and k₂ is the second extinction coefficient for the defined wavelength.

In the structure, the oxide layer makesis in direct contact with the contact film, the first and second attenuationextinction coefficients are equal to 1 or less, and the first and second thicknesses are respectively defined by: h₁=m₁*λ/(4n₁) and h₂=m₂*λ/(4n₂), where m₁ and m₂ are whole numbers.

### CROSS-REFERENCE TO RELATED APPLICATIONS

This application is a national phase entry under 35 U.S.C. § 371 of International Patent Application PCT/EP2024/050979, filed Jan. 17, 2024, designating the United States of America and published as International Patent Publication WO 2024/179735 A1 on Sep. 6, 2024, which claims the benefit under Article 8 of the Patent Cooperation Treaty of French Patent Application Serial No. FR2301768, filed Feb. 27, 2023.

### TECHNICAL FIELD

The field of the present disclosure is that of semiconductors and particularly of optoelectronics. It concerns a semiconductor structure to form one or a plurality of vertical-cavity laser diodes.

### BACKGROUND

Vertical-cavity surface-emitting lasers (VCSELs) are increasingly being developed for the emergent mass-market applications consisting of facial recognition in the field of mobile telephony, in particular, and Lidar (“light detection and ranging”) remote detection for the automobile industry.

Referring to FIG. 1, VCSELs 100 are produced from stacks of layers of III-V semiconductor materials, by way of successive epitaxial growths. The composition, doping and thickness of each layer are precisely controlled to form, on the one hand, an active region 2 consisting of one or more quantum wells allowing the laser beam to be generated, and on the other hand, two Bragg mirrors 3a, 3b that sandwich the active region 2 and consist of an alternation of layers with high and low refraction indices.

It is known to form the stack of layers for VCSELs 100 on a bulk substrate 1, as illustrated in FIG. 1, for example, made of gallium arsenide (GaAs) for laser wavelengths of between 650 nm and 1300 nm, or of indium phosphide (InP) for laser wavelengths of between 1300 nm and 2000 nm. The bulk substrate 1 must have excellent quality, in order to assure the function of an epitaxy seed, and guarantee the quality of the stack of layers. However, when the VCSEL(s) is/are intended to emit via the rear face, i.e., when the laser beam will pass through the bulk substrate 1, the problem arises of absorption of the signal by the substrate 1. For example, an n-type GaAs substrate is conventionally used as a bulk substrate 1 in order to produce the stack of layers for VCSELs 100. A substrate of this type, however, is too absorbent in the laser emission wavelength range (typically 0.5 μm-1.5 μm) to guarantee a high performance level of the VCSELs 100.

In order to address this problem, International Patent Application Publication No. WO2021/125005 proposes carrying out a transfer of layer(s) from a bulk substrate 1 to a support substrate, the properties of which are more suitable for the emission constraints on the rear face of the VCSELs 100.

In order to carry out a transfer of layers, an assembly step is required. The assembly must make it possible to conserve the quality of the layer(s)transferred. The assembly must also avoid adding disturbances to the operation of the VCSEL 100.

### BRIEF SUMMARY

The present disclosure proposes a solution that simplifies the production of vertical-cavity laser diodes (VCSELs) and makes it reliable. In particular, it concerns a semiconductor structure comprising a semi-insulating support substrate made of gallium arsenide, on which there is a stack of semiconductor layers based on III-V elements, defining a lower Bragg mirror, an active laser layer, and an upper Bragg mirror. A semiconductor contact film and an oxide layer, interposed between the stack of layers and the support substrate, have particular characteristics in terms of thickness and optical absorption, in order to provide the laser diodes with a high level of performance, while assuring simple and robust production of the semiconductor structure.

The present disclosure concerns a semiconductor structure to form one or a plurality of vertical-cavity laser diodes, comprising:
a stack of semiconductor layers based on III-V elements defining an upper Bragg mirror, positioned on an active layer constituted by at least one quantum well permitting laser emission at a defined wavelength, the active layer being positioned on a lower Bragg mirror, the laser emission being designed to exit from the stack of semiconductor layers via the lower Bragg mirror;
a semiconductor contact film, positioned directly below the lower Bragg mirror, the contact film having a first thickness and a first complex refraction index known as n₁′=n₁+i.k₁, where n₁ is the first refraction index and k₁ is the first extinction coefficient for the defined wavelength;
a semi-insulating gallium arsenide support substrate having a front face and a rear face;
an oxide layer in contact with the front face of the support substrate, and positioned between the front face and the contact film, the oxide layer having a second thickness and a second complex refraction index known as n₂′=n₂+i.k₂, where n₂ is the second refraction index and k₂ is the second extinction coefficient for the defined wavelength.

The semiconductor structure is distinguished in that:
the oxide layer is in direct contact with the contact film, on the side opposite the lower Bragg mirror;
the first and second extinction coefficients are equal to 1 or less; and
the first and second thicknesses are respectively defined by: h₁=m₁*λ/(4n₁) and h₂=m₂*)/(4n₂), where m₁ and m₂ are whole numbers.

According to advantageous characteristics of the present disclosure, taken alone or according to any combination that can be created:
the first and second extinction coefficients are equal to 0.1 or less;
the contact layer and the oxide layer have extinction coefficients in the wavelength range 0.5 μm-2 μm equal to 1 or less, and preferably equal to 0.1 or less;
the oxide layer is formed by a silicon oxide, a glass, or a zinc oxide;
the lower Bragg mirror comprises fewer than seven alternations of layers of gallium arsenide and aluminum arsenide, for a wavelength λ of between 800 μm and 950 μm;
the semiconductor structure comprises a direct adhesion interface, between the oxide layer and the contact film;
the semiconductor structure comprises a direct adhesion interface between the oxide layer and the support substrate;
the semiconductor structure comprises a direct adhesion interface in the oxide layer.

The present disclosure also concerns a process for production of a semiconductor structure as described above.

According to a first variant, the production process comprises the following steps:
the production of the stack of semiconductor layers on an initial substrate provided with a layer of van der Waals material, in the following order: the upper Bragg mirror formed on the layer of van der Waals material, the active layer formed on the upper Bragg mirror, and the lower Bragg mirror formed on the active layer;
the production of the contact film on the lower Bragg mirror, thus forming a donor structure comprising the initial substrate, the layer of van der Waals material, the stack of semiconductor layers, and the contact film;
the formation of all or part of the oxide layer on the contact film and/or on the support substrate;
the assembly by direct adhesion between the donor structure and the support substrate, along an adhesion interface involving a face of the oxide layer, or being included in the oxide layer;
the separation at the layer of van der Waals material, in order to give rise to the semiconductor structure.

According to a second variant, the production process comprises the following steps:
the production of the contact film on an initial substrate, thus forming a donor structure;
the formation of all or part of the oxide layer on the contact film and/or on the support substrate;
the assembly by direct adhesion between the donor structure and the support substrate, along an adhesion interface involving a face of the oxide layer, or being included in the oxide layer;
the removal of at least part of the initial substrate, giving rise to a free face of the contact film;
the production of the stack of semiconductor layers on the free face of the contact film in the following order: the lower Bragg mirror positioned on the contact film, the active layer positioned on the lower Bragg mirror, and the upper Bragg mirror positioned on the active layer.

Advantageously, the removal step involves separation along an embedded fragile plane parallel to the adhesion interface, and recuperation of some or all of the initial substrate.

### BRIEF DESCRIPTION OF THE DRAWINGS

Other characteristics and advantages of the present disclosure will emerge from the detailed description that will follow, with reference to the appended figures, in which:

FIG. 1 shows a semiconductor structure for the production of a VCSEL according to the prior art;

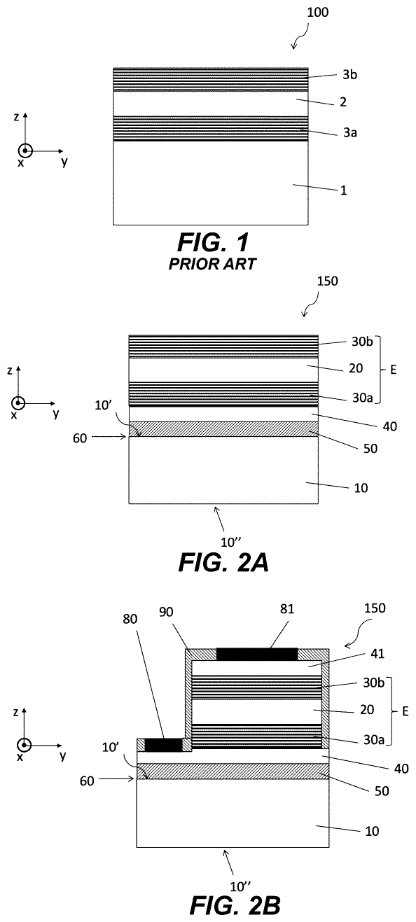

FIGS. 2A and 2B show semiconductor structures according to the present disclosure;

FIGS. 3A and 3B show thickness tables, respectively, for a contact film and for an oxide layer, in an example of a semiconductor structure according to the present disclosure;

FIGS. 4A-4F show steps of a process for production of a semiconductor structure according to a first variant embodiment of the present disclosure;

FIGS. 5A-5F show steps of a process for production of a semiconductor structure according to a second variant embodiment of the present disclosure;

FIG. 6 shows a graph illustrating the reflectivity according to the number of alternations of layers of gallium arsenide and aluminum arsenide, for a Bragg mirror according to the prior art, and for a lower Bragg mirror of a semiconductor structure according to the present disclosure.

Certain figures are schematic representations that, for the purpose of legibility, are not to scale. In particular, the thicknesses of the layers along the axis z are not to scale in relation to the lateral dimensions along the axes x and y.

In the figures, the same references may have been used for elements of the same nature.

### DETAILED DESCRIPTION

The present disclosure concerns a semiconductor structure 150, which is specially designed for optoelectronic applications, in order to form one or a plurality of vertical-cavity laser diodes.

The semiconductor structure 150 can be in the form of a small plate, the diameter of which is, for example, between 50 mm and 200 mm: in this case, it is designed to receive a plurality of optoelectronic components (VCSELs), which can subsequently be singled out. It may alternatively take the form of a vignette of a smaller size, accommodating one optoelectronic component or a group of components.

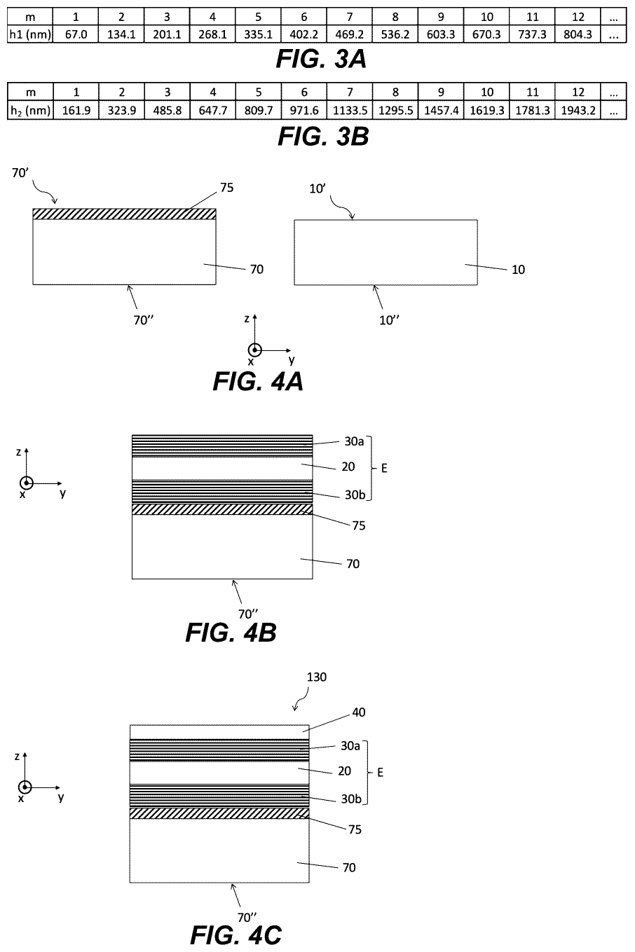

As illustrated in FIG. 2A, the structure 150 comprises a stack E of semiconductor layers based on III-V elements, defining an upper Bragg mirror 30b, an active layer 20 constituted by at least one quantum well permitting laser emission at a defined wavelength 2, and a lower Bragg mirror 30a. The active layer 20 has two faces, one being in contact with the upper Bragg mirror 30b, and the other with the lower Bragg mirror 30a. The terms “upper” and “lower” for the Bragg mirrors 30a, 30b of the stack E are used with reference to the reference system (x, y, z) shown on FIG. 2A, with the direction of the axis z indicating “upwards”; according to the axis z, the reference mirror 30a is thus at a lower level, and the reference mirror 30b is at a higher level in the structure 150. They are also used as a reference for the mirror via which the laser emission with a wavelength λ is designed to exit; this is a so-called rear-face emission, i.e., the laser wave will exit via the lower Bragg mirror 30a, i.e., the one that is closest to the support substrate 10, which will be described subsequently.

The layers 30b, 20, 30a of the stack E, and in general the layers or substrates described hereinafter, extend parallel to a main plane (x, y) and have a thickness along the axis z.

As already known, the active layer 20 can be formed from gallium arsenide (GaAs) and or its ternary or quaternary compounds (such as, in particular, AlGaAs, InGaAs, InGaAsN, etc.); it can alternatively be formed from indium phosphide (InP) and/or its ternary or quaternary compounds (such as, for example, InAsP, GaAlInP, etc.). The Bragg mirrors, constituted by an alternation of layers with low and high refraction indicates, are also known as multi-layers. which can be formed from gallium arsenide (GaAs), aluminum arsenide (AlAs) and their compounds, or from indium phosphide (InP) and its compounds, depending on the nature of the active layer 20. In fact, it should be remembered that the stack E is produced by epitaxy, which makes it necessary to use materials, the lattice parameter and the chemistry of which are perfectly compatible.

The thickness of the stack E can be between 1 and 15 μm.

As previously stated, the semiconductor structure 150 comprises a support substrate 10, which is made of semi-insulating gallium arsenide, and is transparent at the wavelength of the laser, with a front face 10′ and a rear face 10″. The stack of layers E is positioned on the front face 10′. The laser emission with a wavelength λ is designed to exit via the rear face 10″ of the substrate 10. The semi-insulating gallium arsenide, which has a high level of optical transparency, will have low absorption of the laser wave, which is a prerequisite for high-performance functioning of the VCSELs. Its thickness is, for example, between 200 and 2,000 μm.

The structure 150 also comprises a semiconductor contact film 40, which is positioned directly below, and in contact with, the lower Bragg mirror 30a of the stack E. The contact film 40 has a first thickness h₁ and a first complex refraction index n₁′, known as n₁′=n₁ +i.k₁, where n₁ is the first refraction index and k₁ is the first extinction coefficient for the wavelength λ.

Finally, the structure 150 comprises an oxide layer 50, which is in contact with the front face 10′ of the support substrate 10 on one side, and is positioned in contact with the contact film 40 on the other side. As will be described hereinafter with reference to the process for production of the structure 150, the oxide layer 50 will provide a significant advantage in the assembly step, since its surface preparation is easy and proven, and a layer of this type assures excellent quality (low level of defectiveness and high-energy) of direct adhesion (without addition of adhesive material) . Advantageously, the material of the oxide layer 50 is amorphous, such as to limit the stress field associated with the addition of two materials, the crystalline networks of which are not aligned, and/or the lattice parameters of which are different, and so as to avoid the formation of nano-bubbles at the adhesion interface.

The oxide layer 50 has a second thickness h₂ and a second complex refraction index n₂′, known as n₂′=n₂+i.k₂, where n₂ is the second refraction index, and k₂ is the second extinction coefficient for the wavelength λ.

The material of the contact film 40 and the oxide layer 50 are selected such that the first k₁ and second k₂ extinction coefficients are lower than 10, equal to 1 or less, or equal to 0.1 or less (for the wavelength λ). Advantageously, the extinction coefficients of the contact film 40 and the oxide layer 50 are lower than 10, equal to 1 or less, or equal to 0.1 or less in the wavelength range [0.5 μm-2 μm]. They are selected so as to be as close to zero as possible (at least at the wavelength λ), in order to limit the attenuation of the light signal that is designed to pass through the layers 40, 50.

In particular, the contact film 40 can be produced from n-type or p-type GaAs in order to act as an electrical contact layer; it then has an extinction coefficient k₁ that is equal to 0 at a wavelength λ of 940 nm. In the wavelength range λ=1.55 μm, and on a stack based on InP, the contact film 40 can be produced from n-type or p-type InP.

The oxide layer 50 for its part can be formed by a silicon oxide (SiOₓ, SiO₂), the extinction coefficient k₂ of which is equal to 1.1 10⁻³ at λ=940 nm. Other materials can constitute the oxide layer 50, such as zinc oxide (k₂=7.10⁻³ for λ=0.94 μm and k₂=2.10⁻³ for λ=1.55 μm) or a glass.

It will be appreciated that the examples of materials given for the contact film 40 and for the oxide layer 50 are not exhaustive.

In addition, according to the present disclosure, the first h₁ and second h₂ thicknesses, respectively, of the contact layer 40 and the oxide layer 50, are defined by:

h₁=m₁*)/(4n₁) and h₂=m₂*)/(4n₂),

where m₁ and m₂ are whole numbers, which can be identical or different.

These thickness rules, applied to the two layers 40, 50 interposed between the lower Bragg mirror 30a and the support substrate 10, make it possible to assimilate the contact film 40 and the oxide layer 50 to layers of the mirror 30a. This firstly provides the advantage of not disturbing the laser emission, since in fact the wave encounters only a Bragg mirror before entering and passing through the support substrate 10, and not interposed disturbance layers. Secondly, the number of layers necessary in order to produce the lower Bragg mirror 30a can be reduced, since the contact film 40 and the adhesion layer 50 will participate in the reflection of the laser wave.

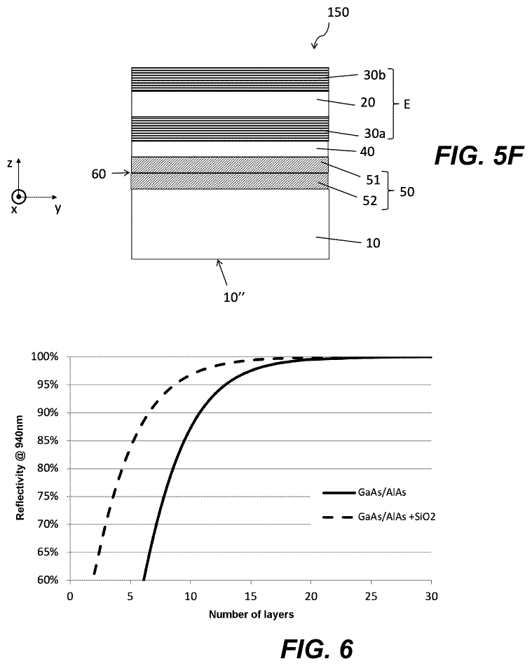

For example, a lower Bragg mirror 30a can comprise fewer than seven alternations of layers (GaAs/AiAs) in order to achieve reflectivity of 95%, instead of thirteen alternations (FIG. 6). According to another example, a lower Bragg mirror 30a, formed from InP and/or its compounds, can comprise fewer than ten alternations of layers in order to achieve reflectivity of 95% instead of over thirty alternations.

The design rule that associates the thickness with the ratio between the wavelength and the refraction index is habitually applied to the multiple layers that form the Bragg mirrors. On the other hand, it is never envisaged in the prior art to apply this same rule to the underlying layers of the lower mirror. In fact, these are habitually selected such that they do not have a refraction index contrast, and consequently do not contribute to the reflection of the light, contrary to the layers that constitute the Bragg mirror.

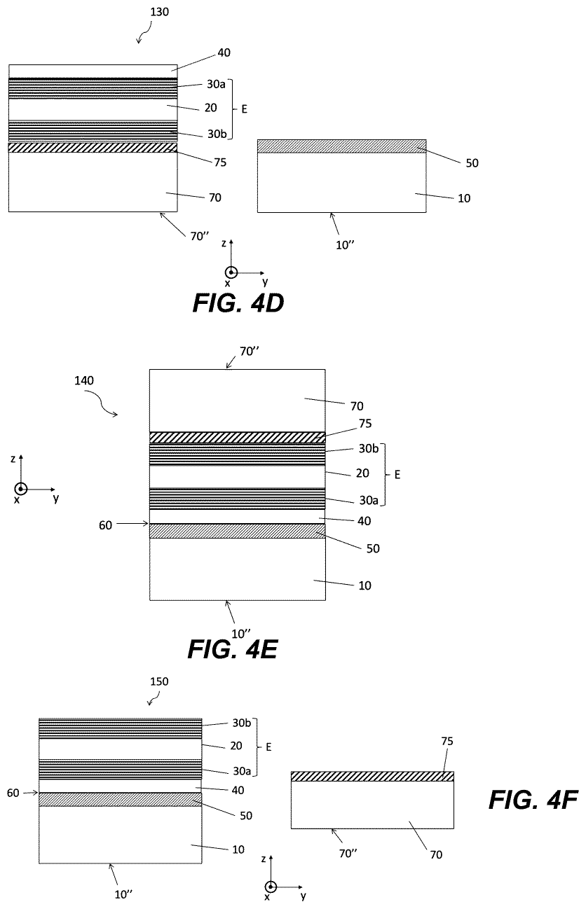

By way of example, in the case of a stack E based on GaAs or its compounds (laser wavelength λ=940 nm), of a contact film 40 made of n-type GaAs and an oxide layer 50 made of SiO₂:
the thickness h₁ of the contact film 40 can be selected from among the thicknesses indicated in the table of FIG. 3A. It will be remembered that the refraction index n₁ is 3.5060 for λ=940 nm.
the thickness h₂ of the oxide layer 50 can be selected from among the thicknesses indicated in the table of FIG. 3B. It will be remembered that the refraction index n₂ is 1.4512 for λ=940 nm.

The semiconductor structure 150 according to the present disclosure is thus particularly suitable for forming vertical-cavity laser diodes (VCSELs) of very good quality, both because the assembly step (required to carry out a transfer of useful layer to the support substrate 10) is simplified and made reliable, and because the laser wave is not subjected to disturbances after exiting from the lower Bragg mirror 30a.

The semiconductor structure 150 according to the present disclosure also comprises a direct adhesion interface 60 that extends on the main plane (x, y), the interface 60 being included in, or adjacent to, the oxide layer 50. The adhesion interface 60 can be situated between the oxide layer 50 and the contact film 40, between the oxide layer 50 and the support substrate 10, or also in the oxide layer 50.

“Direct adhesion” means adhesion that does not require an adhesive material and that is based on a molecular adhesion between the assembled surfaces. There are a number of types of direct adhesion, which especially differ in the temperature conditions, pressure conditions, atmosphere or the treatments carried out prior to bringing the surfaces into contact. Reference can be made to molecular adhesion at ambient temperature with or without prior plasma activation of the surfaces to be assembled, atomic diffusion bonding (ADB), or surface-activated bonding (SAB), etc.

The oxide layer 50, which is particularly favorable to the adhesion, can be selected to be more or less thick according to the requirements, provided that its thickness h₂ complies with the rule associating it with the ratio between the wavelength λ and the refraction index n₂ of the layer 50. This provides great flexibility in carrying out the assembly step, which is often easier with a thickness of oxide layer of 150 nm or more.

FIG. 2B shows a semiconductor structure 150 according to the present disclosure, which has been subjected to additional steps for the purpose of production of the optoelectronic components (VCSELs). A second contact film 41 is formed on the upper Bragg mirror 30b, an electrical contact 80, 81 is formed on each of the two contact films 40, 41, and a dielectric layer 90 is provided around the stack E in order to electrically insulate the stack E. The steps are known and are not described further here.

The process for production of the semiconductor structure 150 is based on technologies of transfer of layers by adhesion and thinning according to the prior art. Reference can be made, in particular, to the SMART CUTTM process, which is particularly suitable for the transfer of thin layers. For the transfer of thicker layers, the 2DLT (“2-D Material-based Layer Transfer”) technology can also be used.

Two variants of the production process according to the present disclosure will now be described.

### First Variant of the Process

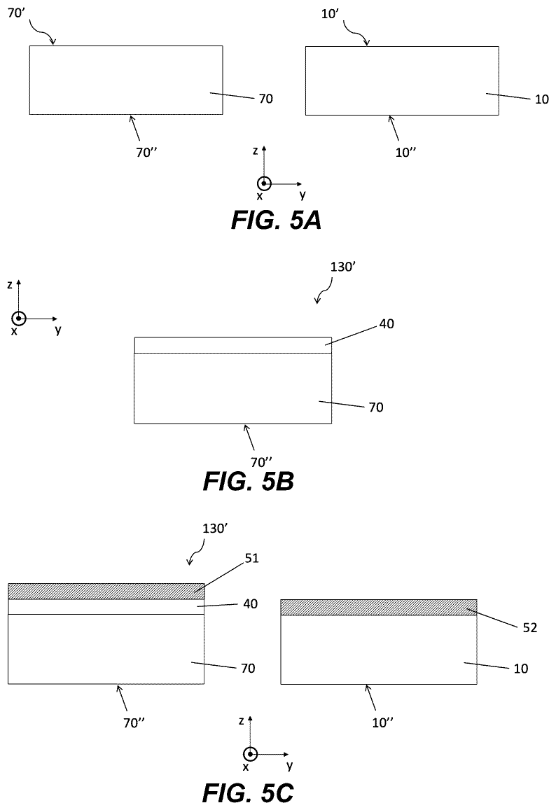

A first step of the process comprises the supply of an initial substrate 70 suitable for production of the stack E of semiconductor layers, for example, an n-type GaAs substrate for a stack based on GaAs and/or its compounds (FIG. 4A). The first step also comprises the supply of the support substrate 10. Each of the substrates 10, 70 has a front face 10′, 70′ and a rear face 10″, 70″.

This first variant is based on 2DLT transfer technology, which involves a material known as 2-D material or van der Waals material (2-D because substantially with two dimensions) interposed between the layer or stack to be transferred and the initial substrate on which the stack is formed, and at the level of which subsequent detachment will be possible. In the present case, the van der Waals material is used to separate the stack E of semiconductor layers from the initial substrate 70.

A layer of van der Waals material 75 is formed on the initial substrate 70. A van der Waals material is defined as the material constituted by atoms that are strongly bonded to one another by covalent or ionic bonds only on the plane of formation of the material (in this case, the plane (x, y)), without strong bonds perpendicular to this plane. Materials such as graphite, graphene, MoS₂, WSe₂, h-BN, etc., are van de Waals materials or 2-D materials. From a practical point of view, it is thus possible to use one or a plurality of layers of graphene (or another 2-D material), preferably a single layer as described, for example, by Celesta Chang et al. in “Remote Epitaxy,” Nature Methods, June 2022, or also in document WO 2017/044577 A1. The graphene layer can be obtained, for example, by means of a method of wet transfer of a layer obtained by CVD onto a catalytic metal substrate. It should be noted that the crystalline pattern of the initial substrate 70 can guide the crystalline growth of the layers of the stack E through the layer of graphene when it is sufficiently fine, preferably consisting of 1 to less than 10, and preferably 1 to 3 layers of graphene.

The second step corresponds to the production of the stack E of semiconductor layers at least on the side of the front face 70′ of the initial substrate 70, on the layer of van der Waals material 75, in the following order: the upper Bragg mirror 30b formed on the layer 75, the active layer 20 formed on the upper Bragg mirror 30b and the lower Bragg mirror 30a formed on the active layer 20 (FIG. 4B). This stack is produced by successive epitaxies using the initial substrate 70 as an epitaxy seed. These steps, known in the prior art, will not be described here.

The third step consists in the production of the contact film 40 on the lower Bragg mirror 30a, thus forming a donor structure 130 comprising the initial substrate 70, the layer of van der Waals material 75, the stack E of semiconductor layers, and the contact film (FIG. 4C). In this case also, the contact film 40 can be produced by epitaxy. It complies with the conditions previously described in terms of thickness and optical properties.

During the fourth step, the oxide layer 50 is formed entirely or partly, on the contact film 40 and/or on the support substrate 10 (FIG. 4D). In other words, the oxide layer 50 can be produced entirely on the donor structure 130 side, or entirely on the support substrate 10 side, as illustrated in FIG. 4D; it can also be formed partly on the donor structure 130 side and partly on the support substrate 10 side: after the assembly (which takes place in the following step of the process), the two parts of the oxide layer 50 will be glued along an adhesion interface 60, in order to constitute together the oxide layer 50 of the semiconductor structure 150.

The oxide layer 50 can be formed by any known deposition technique, such as, in particular, chemical vapor phase deposition (CVD) optionally with PECVD plasma (“Plasma Enhanced Chemical Vapour Deposition”), optionally with a high density plasma (HDP), physical vapor phase deposition (PVD), or atomic deposition ALD (Atomic Layer Deposition). The deposition typically takes place at a temperature of between 100 °C and 700 °C. The oxide layer 50 complies with the conditions previously described in terms of thickness and optical properties.

The fifth step comprises assembly by direct adhesion between the donor structure 130 and the support substrate 10, on the side of their respective front faces 10′, 70′, along an adhesion interface 60, in order to form a glued assembly 140. In the example illustrated in FIG. 4E, the direct adhesion takes place by putting into close contact the free faces of the contact film 40 and the oxide layer 50.

As previously stated, direct adhesion by molecular adhesion at ambient temperature, or alternatively direct adhesion under a controlled temperature and atmosphere (of type ADB or SAB) can be carried out. It will be appreciated that cleaning or surface activations (for example, using a plasma) can be carried out before the faces to be assembled are brought into contact. These surface preparations are known and proved on an oxide layer, which is why it can be advantageous to form part of the oxide layer 50 on each of the surfaces to be assembled. In addition, the fact that the adhesion interface 60 involves a face of an oxide layer 50, or is included in the oxide layer 50, with the layer being able to be relatively thick (typically larger than 150 nm) assures better control of the chemical species involved in the gluing by molecular adhesion, and therefore better quality of the interface 60.

The glued assembly 140 can advantageously be subjected to heat treatment for the consolidation of the adhesion interface 60, typically at a temperature of between 150 °C and 600 °C, for a few minutes to a few hours.

A sixth step of the process corresponds to the separation of the glued assembly 140 at the layer of van der Waals material 75, in order to provide the semiconductor structure 150 according to the present disclosure (FIG. 4F). The separation can be caused by mechanical stress applied in the peripheral region of the glued assembly 140, for example, at the layer of van der Waals material 75, and/or by the addition of an upper layer (not mentioned) providing stress that permits the detachment.

Upon completion of the sixth step, firstly the semiconductor structure 150 is obtained, and secondly the initial substrate 70 (FIG. 4F).

It will be appreciated that, although this first variant has been described, in particular, with reference to 2DLT technology, any other known transfer technique that is compatible with the stack of layers to be transferred could be used in the process according to the present disclosure.

### Second Variant of the Process

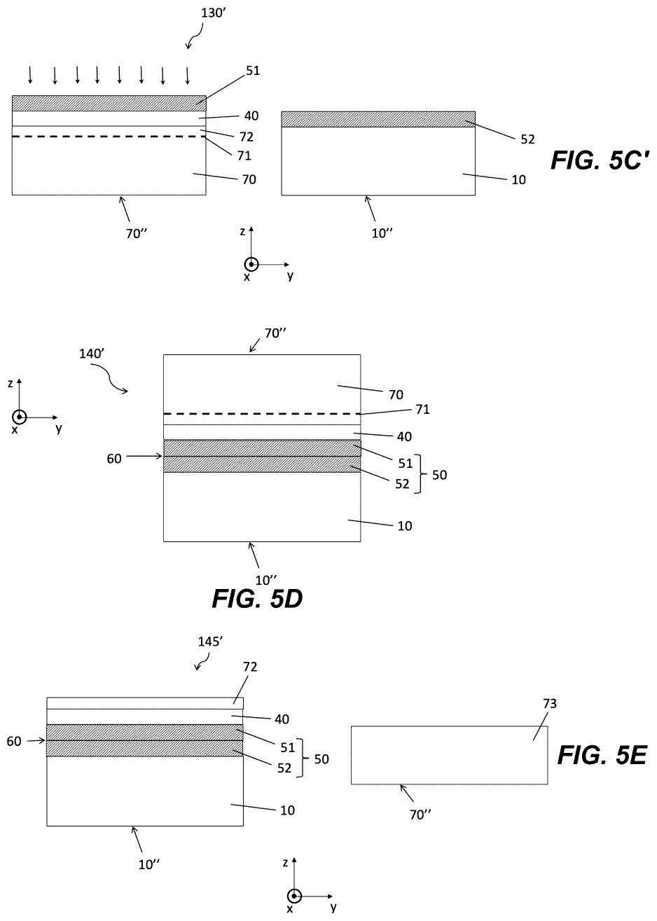

The first step of the process, according to this second variant, comprises the supply of an initial substrate 70 designed for the production of the stack E of semiconductor layers (FIG. 5A). The first step also comprises the supply of the support substrate 10. Each of the substrates 10, 70 has a front face 10′, 70′ and a rear face 10″, 70″.

The second step corresponds to the production of the contact film 40 directly on the initial substrate 70, thus forming a donor structure 130′ (FIG. 5B). The contact film 40 is produced by epitaxy, and will subsequently be used in the process as a seed for the epitaxial growth of the stack E.

During a third step, the oxide layer 50 is formed entirely or partly on the contact film 40 and/or on the support substrate 10 (FIG. 5C). The description provided for the fourth step of the first variant of the process applies here. In the example illustrated in FIG. 5C, part 51 of the oxide layer 50 is formed on the contact film 40, and another part 52 is formed on the support substrate 10; after assembly, these two parts 51, 52 will constitute the oxide layer 50, which must comply with the conditions of thickness and optical properties previously described.

The fourth step of this second variant comprises assembly by direct adhesion between the donor structure 130′ and the support substrate 10, on the side of their respective front faces, along an adhesion interface 60, in order to form a glued assembly 140′. In the example illustrated in FIG. 5D, the direct adhesion takes place by putting the free faces of the parts 51, 52 of the oxide layer 50 into close contact. The description provided for the fifth step (assembly) of the first variant of the process also applies here.

A fifth step of the second variant of the process corresponds to removal entirely or partly of the initial substrate 70 from the glued assembly 140′, in order to give rise to an intermediate structure 145′ comprising the support substrate 10, the oxide layer 50, the contact film 40, and potentially a residual layer 72 of the initial substrate 70 (FIG. 5E).

Advantageously, the removal step involves separation along an embedded fragile plane 71 parallel to the adhesion interface 60, and recuperation of all or part of the initial substrate 70. For this purpose, and as known from the SMART CUTTM process, before the assembly step (fourth step), it is possible to carry out an additional step comprising the introduction of light ions into the initial substrate 70 (or alternatively into the contact film 40), such as to form an embedded fragile plane 71, which, together with a front face of the donor structure 130′, delimits the layer that will be transferred, i.e., part 51 of the adhesion layer, all or part of the contact film 40, and potentially a residual layer 72 of the initial substrate 70 (FIG. 5C′). Typically, in an initial substrate made of GaAs, ionic implantation of helium or hydrogen or of these two ions, at a dose of 1^{E}+16 at/cm² to 5^{E}+17 at/cm² and energy of approximately 100 keV, makes it possible to form the embedded fragile plane 71 that will permit the transfer of 500 nm (He implantation) to 700 nm (H implantation) of the thickness of layers. It should be noted that cleaning and surface preparations can be carried out before and/after the implantation, such as to eliminate potential particular organic and/or metallic contaminations.

Coming back to the fifth step of the process according to the second variant, the step comprises separation along the embedded fragile plane 71, as a result of the presence and/or growth of cavities and micro-cracks in the plane. As is already known, separation of this type takes place, for example, during heat treatment, which can give rise to the development of cavities and putting under pressure thereof, and to the spontaneous propagation of a fracture wave in the embedded fragile plane 71. The separation heat treatment corresponds typically to annealing at 200 °C, lasting, for example, from 30 minutes to 2 hours. Alternatively to, or conjointly with, the heat treatment, separation may be induced by a mechanical stress applied to the embedded fragile plane 71.

Upon completion of the fifth step, firstly an intermediate structure 145′ is obtained, and secondly the remainder 73 of the initial substrate (FIG. 5E). This step can then be completed by surface treatments (cleaning, polishing, etching) or other smoothing treatments, in order to improve the surface quality of the contact layer 40 or the residual layer 72, or also to eliminate this layer 72.

It will be appreciated that, although the fifth step, of removal has been described, in particular, with reference to the SMART CUTTM process, any other known technique of transfer of thin monocrystalline layers could be used in the process according to the present disclosure.

A sixth step of the second variant of the process corresponds to the production of the stack E of semiconductor layers on the intermediate structure 145′. Although a residual layer 72 of the initial substrate 70 was transferred in the preceding step, it is possible to choose to remove it before the production of the stack E. The stack is then formed in the following order: the lower Bragg mirror 30a is formed on the contact film 40, the active layer 20 is formed on the lower Bragg mirror 30a and the upper Bragg mirror 30b is formed on the active layer 20 (FIG. 5F). This stack is created by successive epitaxies using the contact film 40 as an epitaxy seed. These steps, known in the prior art, will not be described here.

Upon completion of this sixth step, a semiconductor structure 150 according to the present disclosure is obtained.

The first and second variants of the production process can comprise additional steps of deposition and etching, making it possible, in particular, to isolate from one another a plurality of laser diodes formed collectively on a single structure 150, to form a contact film 41 on the upper Bragg mirror 30b, and to create an electrical contact 80, 81 on each of the two contact films 40, 41, as illustrated in FIG. 2B.

The semiconductor structure 150 according to the present disclosure is advantageous, since it facilitates greatly the steps of preparation of the surfaces before assembly, and provides an excellent quality of adhesion, as a result of the presence of the oxide layer 50 at the adhesion interface 60. In addition, this layer 50 eliminates the risk of formation of dislocations between the crystals of the assembled materials. The design rules for the thicknesses and the absorption properties, defined for the contact film 40 and the oxide layer 50, prevent these layers, interposed between the lower Bragg mirror 30a and the support substrate 10, from downgrading the performance levels of the VCSELs, by disturbing or absorbing the laser emission exiting, before it passes through the support substrate 10. The contact film 40 and the oxide layer 50 according to the present disclosure also participate in the mirror function, and make it possible to use a smaller number of alternations of layers for the production of the lower Bragg mirror 30a, thus constituting another point of simplification of the production process.

It will be appreciated that the present disclosure is not limited to the embodiments described, and that variant embodiments can be provided without departing from the context of the invention as defined by the claims.

1. A semiconductor structure for forming one or a plurality of vertical-cavity laser diodes, the structure comprising:
a stack of semiconductor layers based on III-V elements defining an upper Bragg mirror, positioned on an active layer including at least one quantum well permitting laser emission at a defined wavelength, the active layer being positioned on a lower Bragg mirror, the laser emission being designed to exit from the stack of semiconductor layers via the lower Bragg mirror;
a semiconductor contact film, positioned directly below the lower Bragg mirror, the contact film having a first thickness and a first complex refraction index known as n₁′=n₁+i.k₁, where n₁ is the first refraction index and k₁ is the first extinction coefficient for the defined wavelength;
a semi-insulating gallium arsenide support substrate having a front face and a rear face; and
an oxide layer in contact with the front face of the support substrate and positioned between the said front face and the contact film, the oxide layer having a second thickness and a second complex refraction index known as n₂′=n₂+i.k₂, where n₂ is the second refraction index and k₂ is the second extinction coefficient for the defined wavelength;
wherein:
the oxide layer is in direct contact with the contact film, on the side opposite the lower Bragg mirror;
the first and second extinction coefficients are equal to 1 or less; and
the first and second thicknesses are respectively defined by: h₁=m₁*λ/(4n₁) and h₂=m₂*λ/(4n₂), where m₁ and m₂ are whole numbers.

2. The semiconductor structure of claim 1, wherein the first and second extinction coefficients are equal to 0.1 or less.

3. The semiconductor structure of claim 2, wherein the contact layer and the oxide layer have extinction coefficients in the wavelength range 0.5 μm-2 μm equal to 1 or less.

4. The semiconductor structure according of claim 3, wherein the oxide layer is formed by a silicon oxide, a glass, or a zinc oxide.

5. The semiconductor structure of claim 4, wherein the lower Bragg mirror comprises fewer than seven alternations of layers of gallium arsenide and aluminum arsenide, aand the defined wavelength is between 800 μm and 950 μm.

6. The semiconductor structure of claim 5, further comprising a direct adhesion interface between the oxide layer and the contact film.

7. The semiconductor structure claim 5, further comprising a direct adhesion interface between the oxide layer and the support substrate.

8. The semiconductor structure claim 5, further comprising a direct adhesion interface in the oxide layer.

9. A method of producing a semiconductor structure according to claim 1, comprising the
producing the stack of semiconductor layers on an initial substrate provided with a layer of van der Waals material, in the following order: the upper Bragg mirror formed on the layer of van der Waals material, the active layer formed on the upper Bragg mirror and the lower Bragg mirror formed on the active layer;
producing the contact film on the lower Bragg mirror, thus forming a donor structure comprising the initial substrate the layer of van der Waals material, the stack of semiconductor layers, and the contact film;
forming all or part of the oxide layer on the contact film and/or on the support substrate;
assembling, by direct adhesion between the donor structure and the support substrate along an adhesion interface involving a face of the oxide layer or being included in the oxide layer; and
separating at the layer of van der Waals material to form the semiconductor structure.

10. A method of producing a semiconductor structure according to claim 1, comprising:
producing the contact film on an initial substrate thus forming a donor structure;
forming all or part of the oxide layer on the contact film and/or on the support substrate;
assembling by direct adhesion between the donor structure and the support substrate along an adhesion interface involving a face of the oxide layer or being included in the oxide layer;
ofremoving at least part of the initial substrate giving rise to a free face of the contact film;
producing the stack of semiconductor layers on the free face of the contact film, in the following order: the lower Bragg mirror positioned on the contact film, the active layer positioned on the lower Bragg mirror, and the upper Bragg mirror positioned on the active layer.

11. The method of claim 10, wherein the removal removing involves separating along an embedded fragile plane parallel to the adhesion interface and recuperating some or all of the initial substrate

12. The semiconductor structure of claim 3, wherein the contact layer and the oxide layer have extinction coefficients equal to 0.1 or less.

13. The semiconductor structure of claim 1, wherein the contact layer and the oxide layer have extinction coefficients in the wavelength range 0.5 μm-2 μm equal to 1 or less.

14. The semiconductor structure of claim 13, wherein the contact layer and the oxide layer have extinction coefficients equal to 0.1 or less.

15. The semiconductor structure of claim 1, wherein the oxide layer is formed by a silicon oxide, a glass, or a zinc oxide.

16. The semiconductor structure of claim 1, wherein the lower Bragg mirror comprises fewer than seven alternations of layers of gallium arsenide and aluminum arsenide, and the defined wavelength is between 800 μm and 950 μm.

17. The semiconductor structure of claim 1, further comprising a direct adhesion interface between the oxide layer and the contact film.

18. The semiconductor structure of claim 1, further comprising a direct adhesion interface between the oxide layer and the support substrate.

19. The semiconductor structure of claim 1, further comprising a direct adhesion interface in the oxide layer.
